(19) United States
(12) Patent Application Publication
(10) Pub. No.: US 2025/0157859 A1
(43) Pub. Date: May 15, 2025

(54) METHODS FOR FABRICATING SEMICONDUCTOR DEVICES BY FORMING AND REMOVING EPITAXIAL (EPI) STRUCTURES FROM AN ENGINEERED SUBSTRATE

(71) Applicant: SemiLEDs Corporation, Chu-Nan (TW)

(72) Inventors: TRUNG TRI DOAN, HSINCHU COUNTY (TW); CHEN-FU CHU, HSINCHU CITY (TW)

(73) Assignee: SemiLEDs Corporation, Chu-Nan (TW)

(21) Appl. No.: 18/937,127

(22) Filed: Nov. 5, 2024

Related U.S. Application Data
(60) Provisional application No. 63/599,041, filed on Nov. 15, 2023.

(51) Int. Cl. H01L 21/78

(52) U.S. Cl. CPC H01L 21/7806

(57) ABSTRACT

A method for fabricating semiconductor devices includes providing an engineered substrate (ES) having a core, an engineered layer (ELY) on the core, and a lattice matching layer (LML) on the engineered layer (ELY). The method also includes providing a plurality of epitaxial (EPI) layers on the engineered substrate (ES). The method also includes forming a plurality of device epitaxial (EPI) structures in the epitaxial (EPI) layers separated by streets, forming a plurality of connecting metal layers (C-ML) connecting the device epitaxial (EPI) structures, and removing the core of the engineered substrate leaving new device structures connected by the connecting metal layers (C-ML). The method can also include attaching a temporary substrate, such as a UV release substrate, to the device epitaxial (EPI) structures, and performing additional fabrication steps, such as the formation of device contacts.

### CROSS REFERENCE TO RELATED APPLICATION

This application claims priority from U.S. Provisional No. 62/599,041, filed Nov. 15, 2023, which is incorporated herein by reference.

### FIELD

This disclosure relates to the fabrication of semiconductor devices and particularly to a method for fabricating semiconductor devices and removing epitaxial structures from an engineered substrate.

Device manufacturing systems have been developed that enable the fabrication of high-performance devices, such as power devices, RF devices, and high brightness light emitting diodes (LEDs). These systems can employ a prefabricated engineered substrate having a standard thickness, size and shape. Engineered substrates are made from materials that are used as the base for the growth of various semiconductor structures or fabrication processes. The engineered substrate can be purchased from a substrate manufacturer, and device epitaxial layers (EPI) can be deposited on the substrate by a fab or device manufacturer. The engineered substrates allow the use of high-quality semiconductor materials in applications where it was previously not possible, as well as providing improved performance and reliability compared to conventional substrates. By way of example, engineered substrates are marketed under the trademark QST® (QROMIS Substrate Technology) by Qromis, Inc. of Santa Clara, CA.

As shown in FIGS. 1A and 1B, an exemplary engineered substrate (ES) 10 includes a CTE matched core 12 having engineered layers 14, 16 on opposing sides thereof. The CTE matched core 12 can comprise a high thermal conductivity and high mechanical strength core material, which has a very closely matched coefficient of thermal expansion to those of device epitaxial layers over a wide temperature range. The engineered substrate (ES) 10 also includes engineered layers (ELY) 18, such as SiO₂, and a Si layer 20 formed on the engineered layers (ELY) 18.

FIG. 2A and FIG. 2B illustrate epitaxial layers (EPI) 22 formed on the Si (111) layer 20 of the engineered substrate (ES) 10. As shown in FIG. 2B, the epitaxial (EPI) layers 22 include an AlN layer 24, a u-GaN layer 26, a 1500 nm n-GaN layer 28, a 5000 nm n-GaN layer 30, a p-GaN layer 32 and an n-GaN layer 34. The epitaxial (EPI) layers 22 can be fabricated using suitable deposition and growth processes that are known in the art. For example, a metal-organic chemical vapor deposition (MOCVD) reactor can be used to form the epitaxial (EPI) layers 22.

In the fabrication of various semiconductor devices, such as power devices, RF devices, and optoelectronic devices such as laser or LEDs (LS), it is advantageous to have free standing epitaxial (EPI) layers 22 by removing epitaxial (EPI) layers 22 from the engineered substrate (ES); thus enabling vertical devices having better electrical, thermal and reliability performance and also lower cost by reclaiming the engineered substrate (ES) 10 for further EPI growth.

The present disclosure is directed to a method for fabricating semiconductor devices by forming and then removing epitaxial (EPI) structures from an engineered substrate (ES).

### SUMMARY

A method for fabricating semiconductor devices includes the steps of: providing an engineered substrate (ES) and providing a plurality of epitaxial (EPI) layers on the engineered substrate (ES). The method also includes the step of forming a plurality of device epitaxial (EPI) structures in the epitaxial (EPI) layers separated by a pattern of streets. In the illustrative embodiment, the device epitaxial (EPI) structures comprise epitaxial (EPI) structure islands (EPI-ISL). The device epitaxial (EPI) structures can include integrated circuits, such as transistors, power driver devices, and other devices as required. The method also includes the step of forming a plurality of connecting metal layers (C-ML) connecting the device epitaxial (EPI) structures. The method also includes the step of removing the device epitaxial (EPI) structures, while still connected by the connecting metal layers (C-ML), from the engineered substrate (ES). The method can also include the steps of attaching a temporary substrate to the device epitaxial (EPI) structures, and performing additional fabrication steps, such as the formation of device contacts and/or metal interconnects.

In an illustrative embodiment, the engineered substrate (ES) comprises a CTE matched core, an engineered layer (ELY) on the core, and a lattice matching layer (LML) on the engineered layer (ELY) configured to facilitate (EPI) growth. Exemplary materials for the engineered layer (ELY) include Si, Al, C and N as well as combinations of these elements. Exemplary materials for the lattice matching layer (LML) include Si, C, GaN. Al₂O₃, AlN and SiC. The engineered layer (ELY) together with the CTE matched core are engineered such that the CTE of the engineered substrate (ES) closely matches that of the epitaxial (EPI) layers. For example, it is desirable to have the CTE of the engineered substrate (ES) to be within +/−25% of the CTE of the epitaxial (EPI) layers at the EPI deposition temperature.

In the illustrative embodiment, the method includes the steps of: forming a metal layer on the epitaxial (EPI) layers having openings in a selected pattern; using the openings in the metal layer to define a plurality of epitaxial structure (EPI-ISL) islands; forming connecting metal layers (C-ML) on the epitaxial (EPI) structure islands (EPI-ISL) leaving a plurality of openings in a selected pattern; and using the openings in the connecting metal layer (C-ML) to remove portions of the insulating layer. In the illustrative embodiment, the connecting metal layers (C-ML) are formed on the metal layers. In an alternate embodiment, the step of forming the epitaxial structure (EPI-ISL) islands comprises etching of the epitaxial (EPI) layers, and the connecting metal layers (C-ML) are formed directly on the device epitaxial (EPI) structures. The method also includes the step of removing the epitaxial (EPI) structure islands (EPI-ISL), while still connected by the connecting metal layers (C-ML), from the core of the engineered substrate (ES) leaving new device structures.

### BRIEF DESCRIPTION OF THE DRAWINGS

The drawings are schematic in nature and may not be to scale.

FIG. 1A is a schematic cross-sectional view of a prior art engineered substrate ES);

FIG. 1B is an enlarged schematic perspective view of the engineered substrate (ES) taken along section line 1B-1B of FIG. 1A;

FIG. 2A is a schematic side elevation view of a prior art epitaxial (EPI) layers on the engineered substrate (ES);

FIG. 2B is a schematic cross-sectional view of the prior art epitaxial (EPI) layers on the engineered substrate (ES);

FIG. 3A is a schematic cross-sectional view illustrating steps of the method of providing an engineered substrate (ES) and providing epitaxial (EPI) layers on the engineered substrate (ES);

FIG. 3B is a schematic cross-sectional view illustrating the step of depositing contact metals on an upper surface of the epitaxial (EPI) layers;

FIG. 3C is a schematic cross-sectional view illustrating the step of forming a metal layer on the contact metals having openings in a selected pattern;

FIG. 3D is a schematic cross-sectional view illustrating the step of forming a plurality of device epitaxial (EPI) structures separated by streets in the epitaxial (EPI) layers;

FIG. 3E is a schematic plan view of the engineered substrate (ES) following the step of forming the device epitaxial (EPI) structures;

FIG. 3F is an enlarged portion of FIG. 3E taken along section line 3F of FIG. 3E illustrating the device epitaxial (EPI) structures separated by streets;

FIG. 3G is a schematic cross-sectional view illustrating the step of forming a plurality of connecting metal layers (C-ML) connecting the device epitaxial (EPI) structures;

FIG. 3H is a schematic plan view of the engineered substrate (ES) following the step of forming the connecting metal layers (C-ML) in a first pattern;

FIG. 3I is a schematic plan view of the engineered substrate (ES) following the step of forming the connecting metal layers (C-ML) in an alternate second pattern;

FIG. 3J is a schematic cross-sectional view illustrating the step of removing selected portions of an engineered layer (ELY);

FIG. 3K is a schematic cross-sectional view illustrating the step of removing the engineered substrate (ES) from the device epitaxial (EPI) structures;

FIG. 3L is a schematic cross-sectional view illustrating the step of attaching a temporary substrate to the device epitaxial (EPI) structures;

FIGS. 3M-3N are schematic views illustrating an example of GaN peel and crack due to a too thick metal layer;

FIGS. 3O-P are schematic views illustrating an example of no GaN crack by optimizing the metal layer;

FIG. 3Q is a schematic cross-sectional view illustrating a device epitaxial (EPI) structures on a temporary substrate;

FIG. 3R is a schematic cross-sectional view illustrating device epitaxial (EPI) structures separated from the temporary substrate;

FIG. 4A is a schematic cross-sectional view illustrating alternate embodiment connecting metal layers (C-ML) in the form of elongated straps interconnecting multiple epitaxial (EPI) structure islands (EPI-ISL);

FIG. 4B is a schematic plan view of the alternate embodiment connecting metal layers (C-ML) forming a crisscross electrical network;

FIG. 4C is an alternate embodiment of the method in which the connecting metal layers (C-ML) are also formed along the side walls of the device epitaxial (EPI) structures leaving the remaining street areas open;

FIG. 5A is a schematic cross-sectional view illustrating an alternate embodiment of the method wherein connecting metal layers (C-ML) are formed directly on device epitaxial (EPI) structures;

FIG. 5B is a schematic cross-sectional view illustrating the step of forming the connecting metal layers (C-ML) directly on device epitaxial (EPI) structures;

FIG. 5C is an alternate embodiment of the method in which the connecting metal layers (C-ML) are formed of along the corner side walls of the device epitaxial (EPI) structures;

FIG. 5D is a schematic plan view of the alternate embodiment connecting metal layers (C-ML);

FIGS. 6A-6C are schematic cross-sectional view illustrating an exemplary connecting metal layers (C-ML) fabrication sequence; and

FIGS. 7A-7E are schematic cross-sectional view illustrating another exemplary connecting metal layers (C-ML) fabrication sequence.

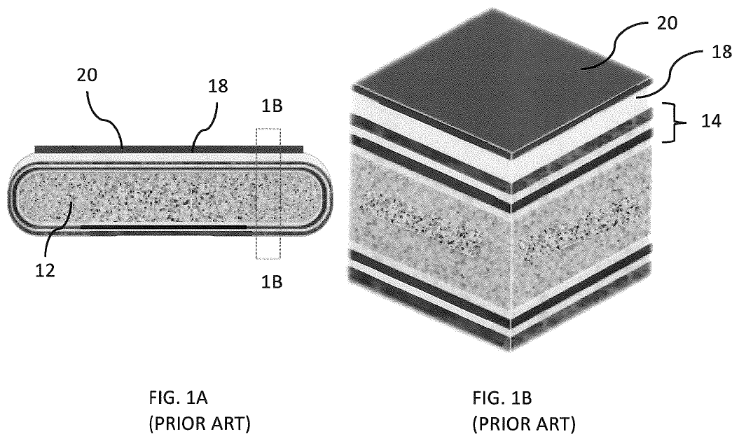

### DETAILED DESCRIPTION

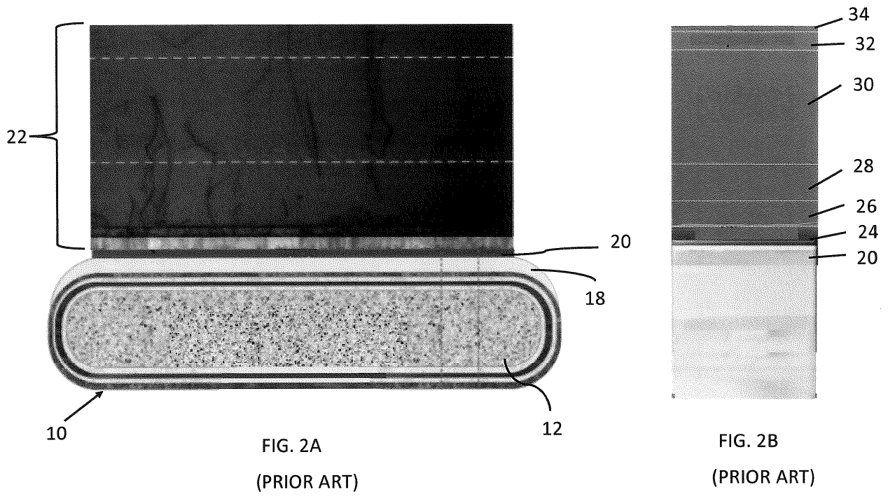

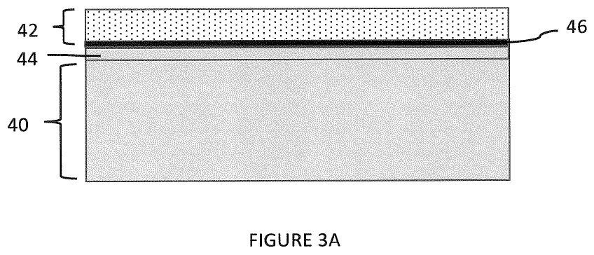

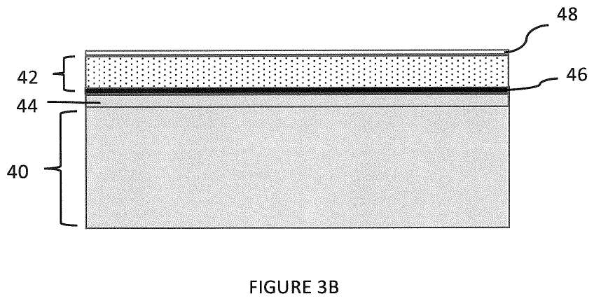

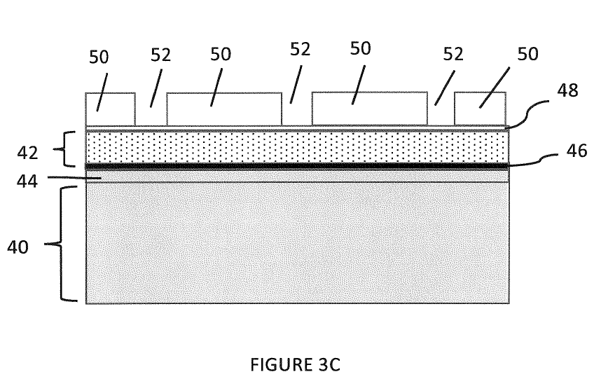

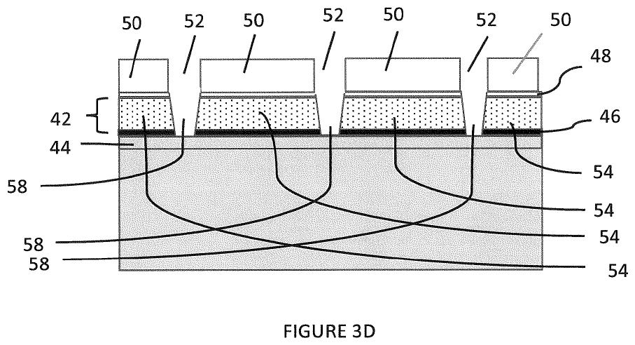

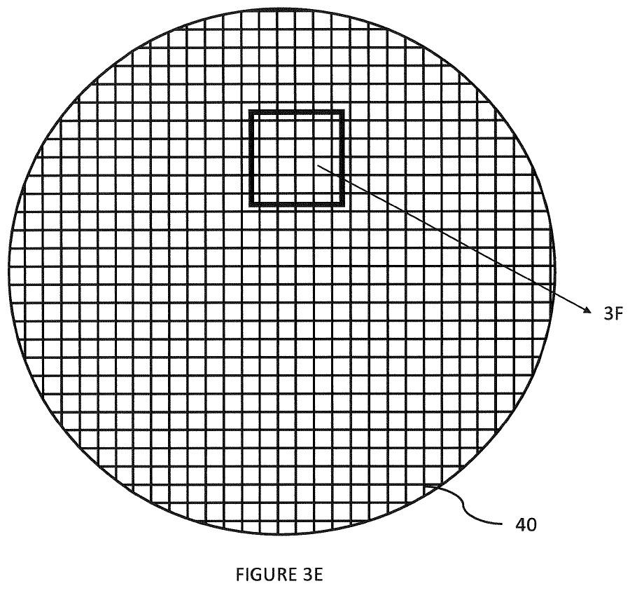

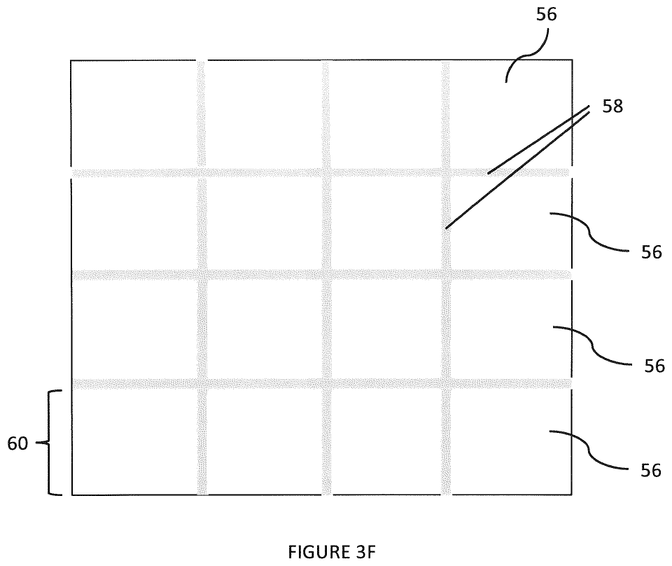

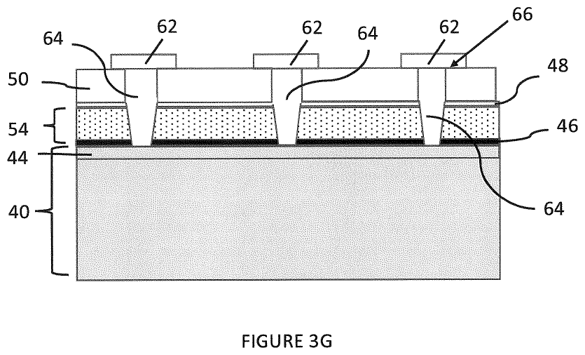

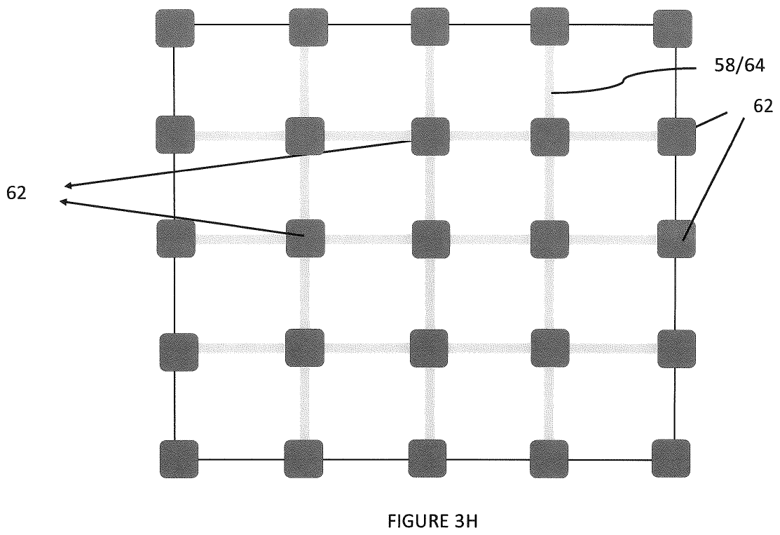

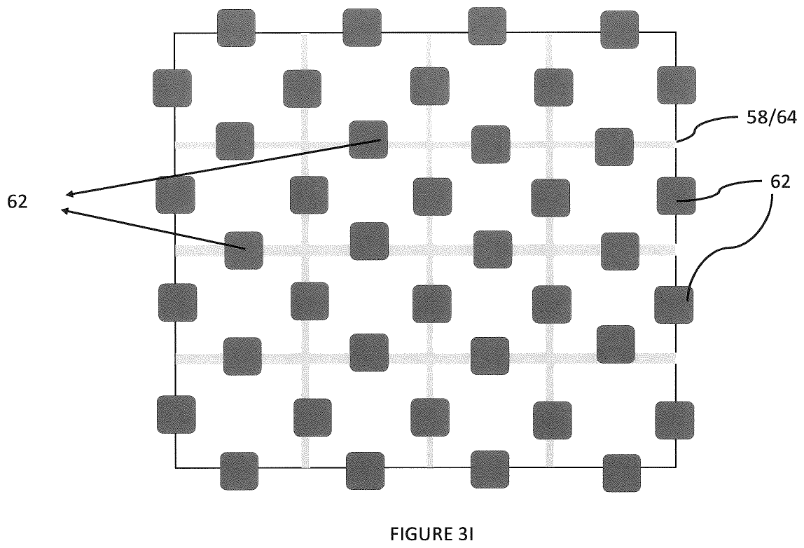

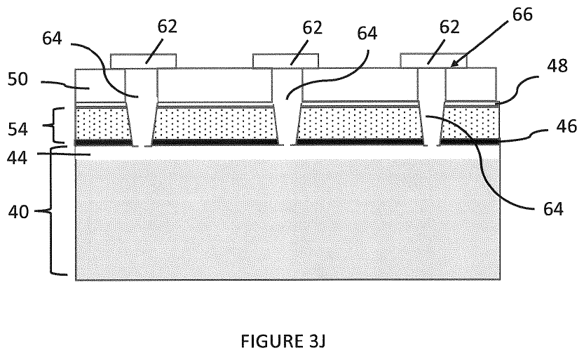

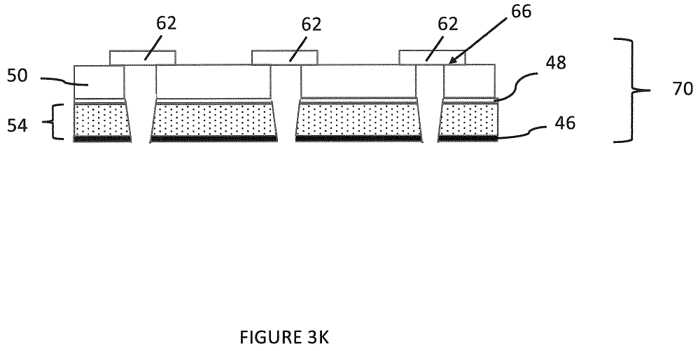

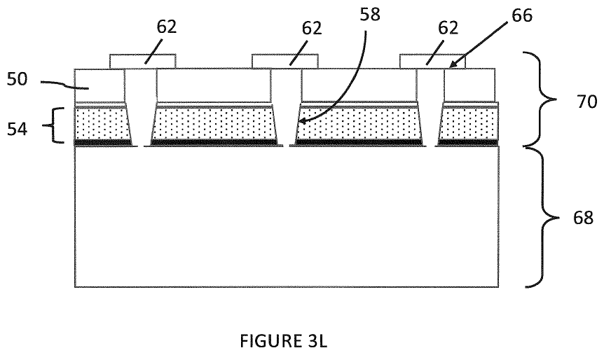

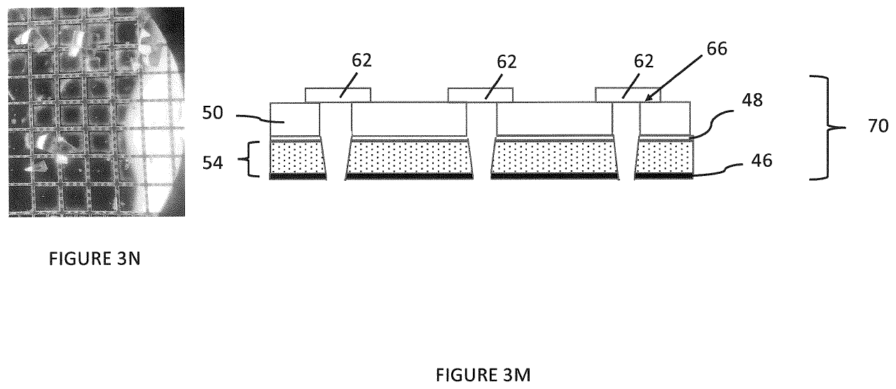

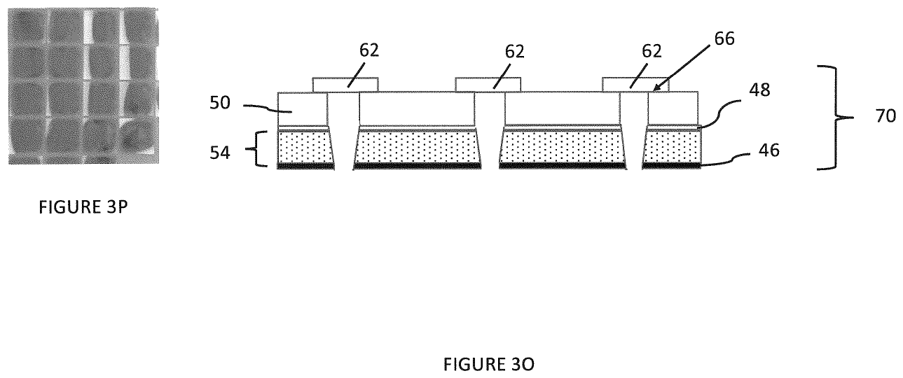

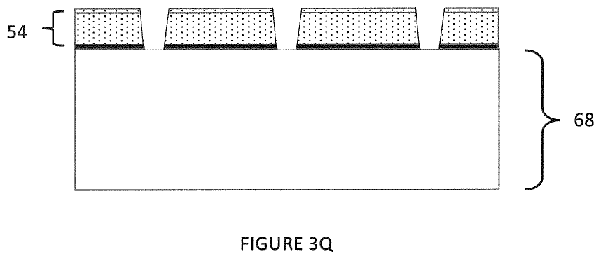

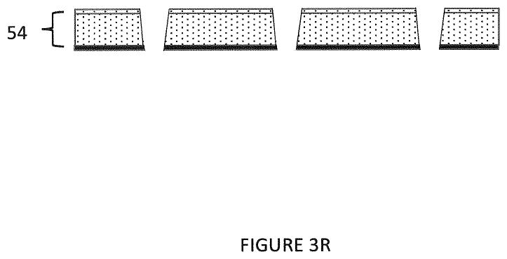

Steps in a method for fabricating semiconductor devices are illustrated in FIGS. 3A-3R. Referring to FIG. 3A, the step of providing an engineered substrate (ES) 40 and the step of providing epitaxial (EPI) layers 42 on the engineered substrate (ES) 40 are illustrated. The engineered substrate (ES) 40 can be configured substantially as previously described for the prior art engineered substrate 10 (FIG. 2A). The engineered substrate (ES) 40 includes an engineered layer (ELY) 44 and a lattice matching layer (LML) 46 on the engineered layer (ELY) 44. Exemplary elements for the engineered layer (ELY) 44 include O, N, C, and Si. The engineered layer (ELY) 44 can also comprise oxide or nitride containing compounds, such as SiO₂, Si₃N₄, and Al₂O₃. The engineered layer (ELY) 44 has engineered properties that make it a suitable material for bonding the lattice matching layer (LML) 46. Exemplary materials for the lattice matching layer (LML) 46 include Si, C, SiC, GaN, AlN, AlGaN, InGaN, AlCGaN, and AlSiGaN. These materials have lattice parameters that closely match the lattice parameters of the grown epitaxial (EPI) layers 42. For example, one element of the lattice matching layer (LML) 46 usually comprises a similar element needed for epitaxial growth of the epitaxial (EPI) layers 42, such as Si, Al, C, and Ni. A commercial example, for the engineered substrate (ES) 40 can comprise a QST® substrate manufactured by Qromis, Inc. of Santa Clara, CA and having a thickness of from 100 to 2000 μm. The engineered layer (ELY) 44 can have a thickness of from 0.1 μm to 5 μm. The lattice matching layer (LML) 46 can have a thickness of about 0.1 μm to 5 um. However, it is to be understood that these thicknesses, as well as the manufacturing method, are exemplary as other thicknesses and manufacturing methods known in the art can be employed.

Still referring to FIG. 3A, the epitaxial (EPI) layers 42 can be configured substantially as previously described for the prior art epitaxial layers (EPI) 22 (FIG. 2A). Exemplary materials for the epitaxial (EPI) layers 42 include Si, C, GaN, AlN, SiC, AlGaN, InGaN, AlCGaN, and AlSiGaN. The epitaxial (EPI) layers 42 can be fabricated using suitable deposition and growth processes that are known in the art. For example, metal-organic chemical vapor deposition (MOCVD), MBE, and HPCVD can be used to form the epitaxial (EPI) layers 42. Depending on the desired electrical performance of the desired epitaxial structures and devices, various epitaxial layers and structures can be fabricated on the lattice matching layer (LML) 46. As an example, for a Si IC device, the lattice matching layer (LML) 46 can comprise a Si epitaxial. As another example, for an LED device, the lattice matching layer (LML) 46 can comprise GaN, AlGaN, InGaN, or AlN. The epitaxial (EPI) layers 42 can comprise at least one of the following elements Ga, Si, C, Al, and In. Many metal organic compounds (MO) having CHx can be used together with nitrogen containing gases (e.g., NH₃, N₂) for epitaxial growth. The epitaxial (EPI) layers 42 can also be doped with Al, In or Si to adjust a band gap in an LED device. The epitaxial (EPI) layers 42 can have a thickness of between 1-50 μm. The separate layers of the epitaxial (EPI) layers 42 can have the thicknesses shown in FIG. 2B. It is to be understood that these thicknesses, as well as the manufacturing method, are exemplary, as other thicknesses and manufacturing methods known in the art can be employed.

Rather than being fabricated from scratch, the engineered substrate (ES) 40 with the above-described layers can be provided as a unit purchased from Shin-Etsu Chemical Co., Ltd. of Tokyo, Japan. In addition to producing QST® substrates, Shin-Etsu Chemical Co., Ltd. also offers GaN-grown QST® substrates upon customer request. Currently, the company markets substrates with 6″ and 8″ diameters, with the sample 12″ substrates are available. One advantage of the QST® substrate is its ability to match the coefficient of thermal expansion (CTE) of the desired epitaxial (EPI) structures such as GaN. This characteristic mitigates warpage and cracking issues in the epitaxial (EPI) layers 42, enabling the formation of thick, large-diameter GaN epitaxial layers of superior quality.

Referring to FIG. 3B, the method further includes the step of depositing contact metals 48 on an upper surface of the epitaxial (EPI) layers 42. For the epitaxial (EPI) layers 22 shown in FIG. 2B, the contact metals 48 can be deposited onto the surface of the n-GaN layer 34 (FIG. 2B). The contact metals 48 can be deposited using a suitable deposition process, such as sputtering, dip coating, or thermal deposition. Exemplary metals for the contact metals 48 include Ni, Cu, Ti, Cr, W, Au and Pt. The contact metals 48 can be formed as a continuous layer or as a stack of different metals such as a Ti/Cu or TiW/Cu stack. As another alternative, a non-metal such as epoxy, silicone, or acrylic can be used in place of the above metals.

Referring to FIG. 3C, the method further includes the step of forming a metal layer 50 on the contact metals 48 having metal layer openings 52 in a selected pattern. The metal layer 50 can be formed with the metal layer openings 52 using an additive process such as a photolithographic process in which a photomask (not shown) is formed with photomask openings (not shown) corresponding to the selected pattern of the metal layer openings 52 in the metal layer 50. A deposition process such as chemical vapor deposition (CVD) can then be used to deposit the metal layer 50 into the photomask openings (not shown) followed by removal of the photomask (not shown). By way of example, the metal layer 50 can comprise one or more metals such as Ni, Co, Cu, Ti, Cr, Mo, W, Au, Ag and Pt. Solid portions of the metal layer 50 align with desired active areas in the device epitaxial (EPI) structures 54 (FIG. 3D) to follow. As another alternative, a non-metal such as epoxy, silicone, or acrylic can be used in place of the above metals. As another alternative, the metal layer 50 can be formed with the metal layer openings 52 using as a process which can include the removal of the metal layer 50 to form the openings 52 using conventional metal deposition, photo masking and metal etching. For applications in which the metal layer 50 makes good adhesion to epitaxial (EPI) layers 42, the contact metals 48 would not be necessary or needed. However, if an electro plating process is used to form the metal layer 50 (e.g., EP of Cu), the contact metals 48 would be needed to act as a seed layer to form the metal layer 50. In an exemplary process, a patterned photo resist layer (not shown) can be employed allowing the metal layer 50 to form in openings of the photo resist layer on top of contact metals 48, which functions as a seed layer during the EP process. Following completion of the EP process, the patterned resist layer can be removed together with the contact metals 48 not covered by the metal layer 50 to expose the surface of the EPI layers 42 not covered by the contact metals 48 and metal layer 50.

Referring to FIG. 3D, the method further includes the step of using the metal layer 50 to form a plurality of device epitaxial (EPI) structures 54 in the epitaxial (EPI) layers 42 having active areas separated by streets 58. This step can be performed by removing portions of the epitaxial (EPI) layers 42, the lattice matching layer (LML) 46 and some portion or all of the engineered layer (ELY) 44 using the metal layer openings 52. Various etching methods can be used to perform this step including dry etching (e.g., inductively coupled plasma reactive ion etching), laser cutting, saw cutting, wet etching, water jetting and vapor HF for oxide etching. These methods can be employed individually or in combination. For example, a fluorine containing gas or liquid can be used to etch SiO₂ for applications where SiO₂ is used as an engineered layer (ELY) 44. As shown in FIG. 3E, the engineered substrate (ES) 40 can be in the form of a semiconductor wafer. As shown in FIG. 3F, the streets 58 are in a crisscross pattern. As also shown in FIG. 3F, the device epitaxial (EPI) structures 54 comprise epitaxial (EPI) structure islands (EPI-ISL) 60 with a polygonal outline in a checker-board pattern, separated by the streets 58 on four sides.

Referring to FIGS. 3G, 3H and 3I, the method further includes the step of forming a plurality of connecting metal layers (C-ML) 62 connecting the device epitaxial (EPI) structures 54, and the step of defining a plurality of second openings 64 (FIG. 3G) aligned with the streets 58 (FIG. 3H) to the engineered layer (ELY) 44. The connecting metal layers (C-ML) 62 can have various designs. In addition, the design must form the openings 64 (FIG. 3G) in the streets 58 to the engineered layer (ELY) 44. FIG. 3H illustrates a first embodiment in which the connecting metal layers (C-ML) 62 are formed on the four corners of the device epitaxial (EPI) structures 54 with each adjacent device epitaxial (EPI) structure 54 connected. FIG. 3I illustrates a second embodiment in which the connecting metal layers (C-ML) 62 are formed in the middle of the sides of the device epitaxial (EPI) structures 54. In both embodiments, the connecting metal layers (C-ML) 62 have a square peripheral outline, however other polygonal and circular outlines can be employed, or any other outlines, as long as the connecting metal layers (C-ML) 62 are strong enough to hold the device epitaxial (EPI) structures 54 together. In both embodiments, the connecting metal layers (C-ML) 62 connect the device epitaxial (EPI) structures 54 forming an interconnected physical structure.

The connecting metal layers (C-ML) 62 can comprise one or more metals selected from the group consisting of Ni, Co, Cu, Ti, Cr, Mo, W, Au, Ag and Pt. The connecting metal layers (C-ML) 62 can also comprise another material such as ITO, AlN, Si₃N₄, silicone, epoxy, or acrylic. In an illustrative embodiment, the connecting metal layers (C-ML) 62 are formed by depositing a second metal 66 followed by a photolithographic deposition process to be further described. Alternately, the connecting metal layers (C-ML) 62 can be formed using various methods such as evaporation, sputtering, electroplating, screen printing, damascene or any other method configured to deposit a conductive material in a selected pattern. The examples to follow disclose two exemplary methods for forming the connecting metal layers (C-ML) 62.

Referring to FIG. 3J, the method further includes the step of further removing the engineered layer (ELY) 44 contacting the lattice matching layer (LML) 46 under the device epitaxial (EPI) structures 54 to separate the engineering substrate (ES) 40 from the device epitaxial (EPI) structures 54. Portions of the engineered layer (ELY) 44 in the openings 64 may have been removed proximate to the device epitaxial (EPI) structures 54 by the previously described etching step. In addition, accelerated horizontal etching of the device epitaxial (EPI) structures 54 under the lattice matching layer (LML) 46 may be needed to separate the engineered substrate (ES) 40 from the device epitaxial (EPI) structures 54. By way of example, with the engineered layer (ELY) 44 comprising SiO₂, a suitable removal method comprises vapor etching using HF or other oxide etching techniques such as atmospheric plasma having CHyFx and Oxygen. However, other selective etching processes can also be employed. For wet chemical etching, to enhance the horizontal engineered layer (ELY) 44 etch rate, one can include the use of high frequency sound wave such as ultrasonics having 10 KHz to 200 KHz frequency and megasonics having 200 KHz to 10 Mhz frequency. This technique further increases the horizontal wet etch rate of the engineered layer (ELY) 44 to minimize the damage to engineered substrate (ES) 40 during etching (e.g., >2× reduction in surface roughness was found with the use of high frequency sound waves). For example, high frequency sound waves traveling through a liquid containing a wet etch chemical having fluorine ions would etch the engineered layer (ELY) 44 faster (more than 2×) than no sound waves. High frequency sound waves create tiny bubbles called cavitation which implode and release energy to the etching sites causing the increase in etch rate inside the channels under the device epitaxial (EPI) structures 54. During ultrasonics or megasonics wet etching, bubbles are generated, imploded and forming even smaller bubbles floating in the etching liquid. Some bubbles coalesce and form large bubbles and stop the transport of fresh chemical to the etch sites under the device epitaxial (EPI) structures 54. This phenomenon increases as the aspect ratio of the etch channel becomes higher as etching progresses deeper under device epitaxial (EPI) structures 54. Here it is important to have the wafers positioned vertically in the bath allowing the bubbles to escape to the surface of the etch bath due to Archimedes forces. The use of mechanical shaking during ultrasonics or megasonics wet etching alone or together with a vertical positioning of the wafers in the bath can also improve the horizontal etch rate and provides a reproducible etch.

Still referring to FIG. 3J, the method can further include the step of optimizing the thickness of the metal layer 50 to prevent damage to the device epitaxial (EPI) structures 54 from stress after separation from the engineered substrate (ES) 40. Since the metal layer 50 is exerting stress on the device epitaxial (EPI) structures 54, this stress can cause the device epitaxial (EPI) structures 54 to crack or break if the stress results is a high enough force to exceed the material Young's modulus. This condition is shown in FIGS. 3M and 3N. With an optimal thickness for the metal layer 50, no cracking occurs. This condition is shown in FIGS. 3O and 3P.

Referring to FIG. 3K, the method further includes the step of physically separating the engineered substrate (ES) 40 from the device epitaxial (EPI) structures 54. This step can also be performed using chemical exfoliation processes using a liquid. The separated structure 70 includes the device epitaxial (EPI) structures 54 having the metal layer 50 thereon, and the connecting metal layers (C-ML) 62 physically connecting the device epitaxial (EPI) structures 54. The engineered substrate 40 can be refurbished and reused if desired.

Referring to FIG. 3L, the method can also include the step of attaching a temporary substrate 68 to the device epitaxial structures 54. An example of a temporary substrate 68 comprises UV release substrate. Any gaps can be filled with a polymer material such as resist. The method can also include the step of performing other fabrication processes such as forming device contacts. Following the fabrication process, the temporary substrate 68 can be removed. For a temporary substrate 68 in the form of a UV release substrate one could expose the UV substrate to UV radiation using LED light sources or laser. In addition, the device epitaxial (EPI) structures 54 can be separated into arrays of two or more epitaxial structures connected by at least one conductive connecting metal layers (C-ML) 62. In addition, as shown in FIG. 3Q, the device epitaxial (EPI) structures 54 on the temporary substrate 68 can be separated from the metal layer 50, to be ready for further processing or uses. In addition, as shown in FIG. 3R, the device epitaxial (EPI) structures 54 can be separated from the temporary substrate 68, to be ready for further processing or uses.

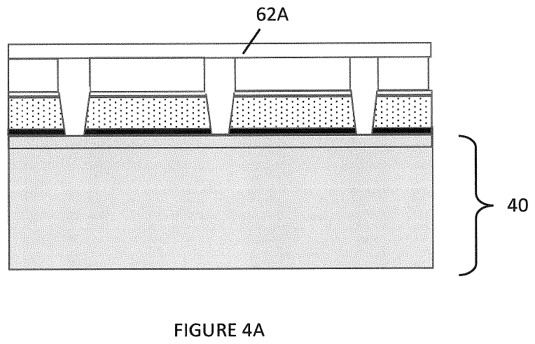

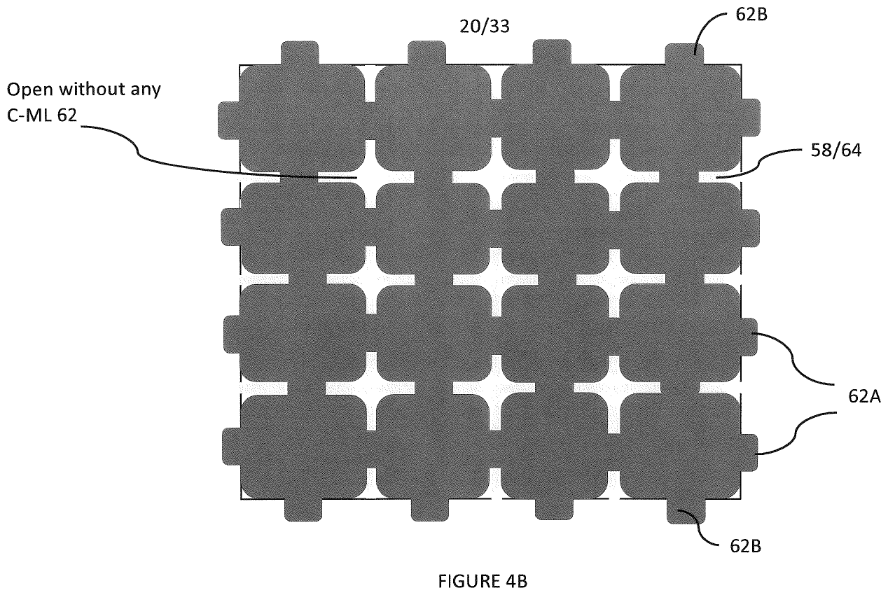

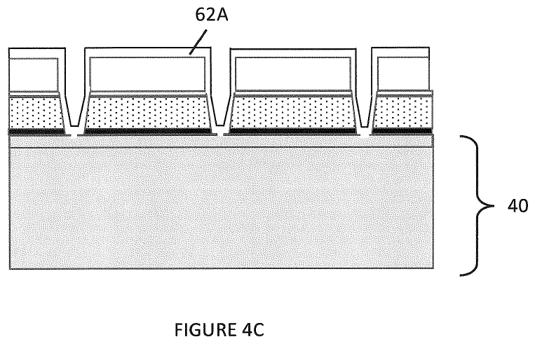

Referring to FIGS. 4A, 4B and 4C, alternate embodiment connecting metal layers (C-ML) 62A and 62B are illustrated. The connecting metal layers (C-ML) 62A and 62B are substantially similar to the previously described connecting metal layers (C-ML) 62 but comprise elongated metal straps that electrically connect all of the device epitaxial (EPI) structures 54 in a crisscross electrical network. In addition, the connecting metal layers (C-ML) 62A and 62B bisect the device epitaxial (EPI) structures 54 and are oriented generally parallel to the streets 58. FIG. 4C illustrates an alternate embodiment of the method in which connecting metal layers (C-ML) 62A and 62B are also formed of along the street side walls of the device epitaxial (EPI) structure 54A leaving the remaining street areas open.

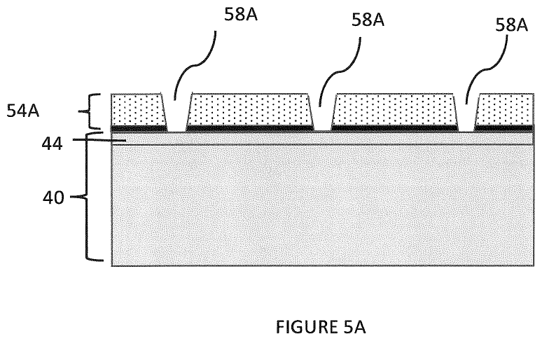

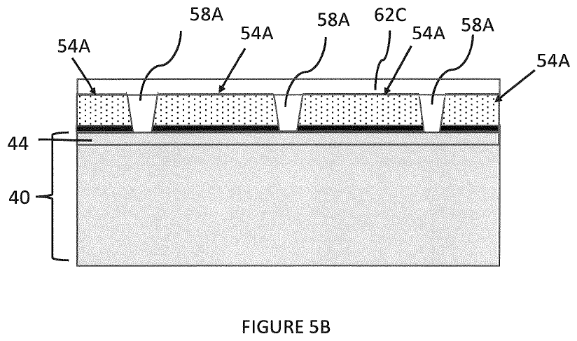

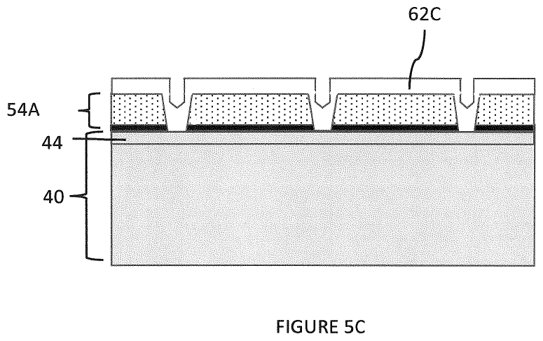

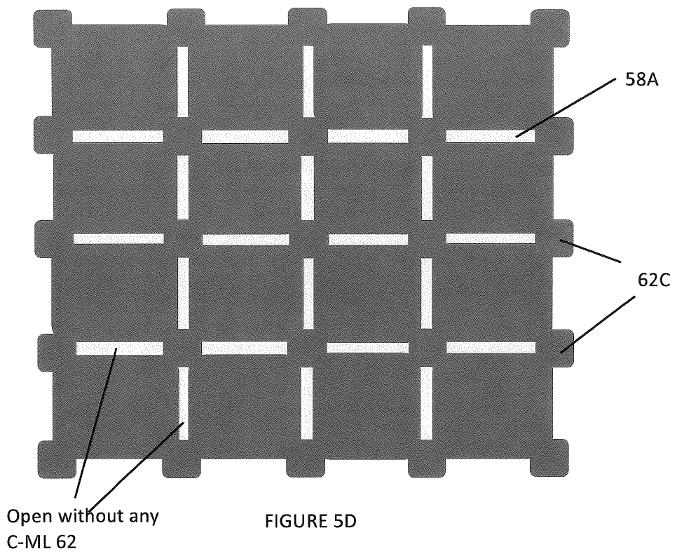

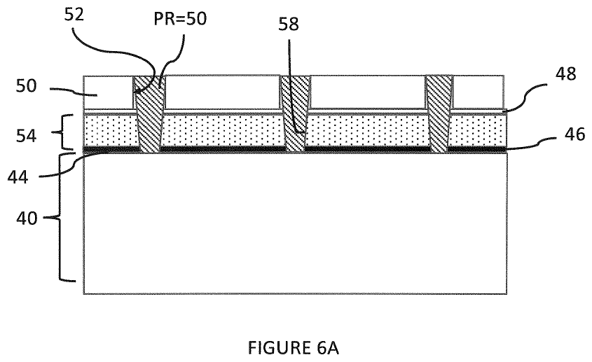

Referring to FIGS. 5A, 5B, 5C and 5D, an alternate embodiment of the method is illustrated. In this embodiment, the step of forming the metal layer 50 (FIG. 3C) on the contact metals 48 (FIG. 3C) is not performed. A plurality of device epitaxial (EPI) structures 54A are defined using a subtractive process such as dry etching (e.g., inductively coupled reactive ion etching or ICP/RIE), laser cutting, saw cutting, diamond cutting, wet etching or water jetting. In addition, the connecting metal layers (C-ML) 62C are formed directly on the device epitaxial (EPI) structures 54A substantially as previously described. FIG. 5C illustrates an alternate embodiment of the method in which the connecting metal layers (C-ML) 62C are also formed along the corner side walls of the device epitaxial (EPI) structure 54A.

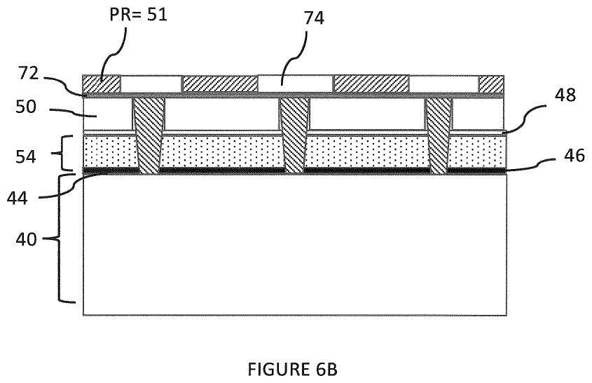

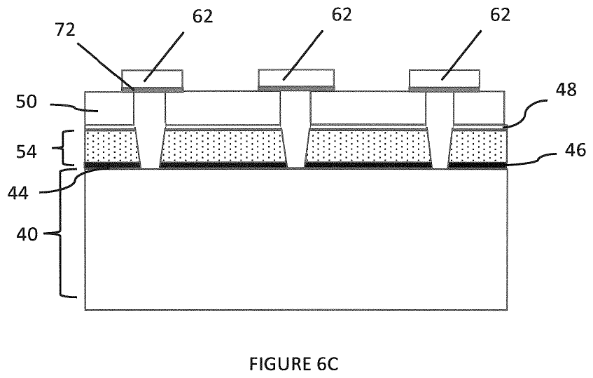

Example 1: Referring to FIGS. 6A-6C, an exemplary fabrication sequence for forming the connecting metal layers (C-ML) 62 (FIG. 6C) is illustrated. In FIG. 6A, a PR=50 photoresist is formed in the metal layer openings 52 and in the streets 58 and is patterned substantially as shown. In FIG. 6B, a second metal layer 72 is formed, followed by patterning of a PR=51 photoresist, followed by an electroplated EP connecting metal layer 74. In FIG. 6C, etching of the second metal layer 72 is followed by removal of PR=51 photoresist and PR=50 photoresist leaving the connecting metal layers (C-ML) 62. In this example the connecting metal layers (C-ML) 62 can comprise Cu. Copper is a favored metal due to its high conductivity, a melting point of about 1085° C. and a boiling point of about 2562° C.

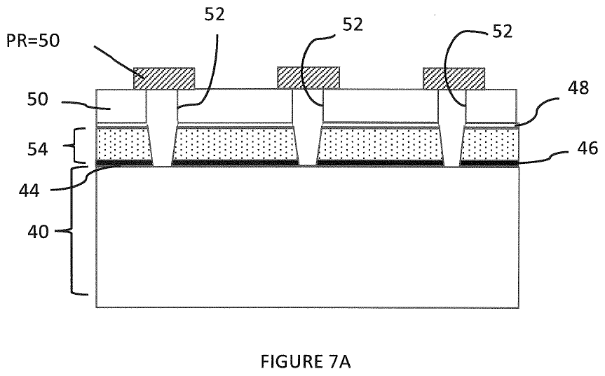

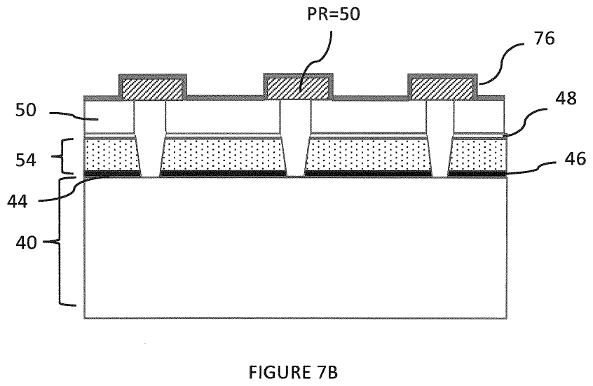

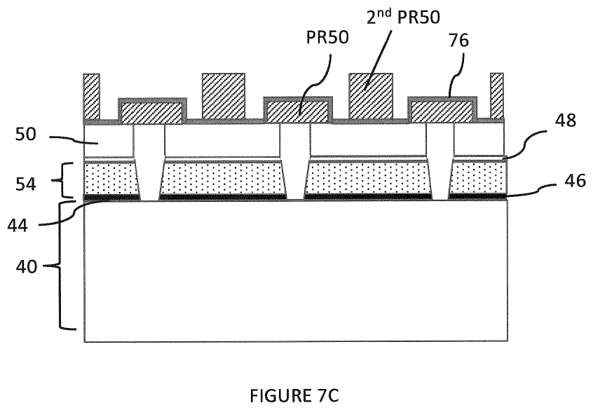

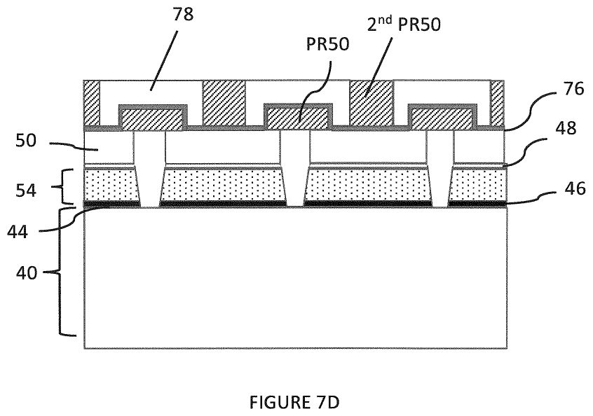

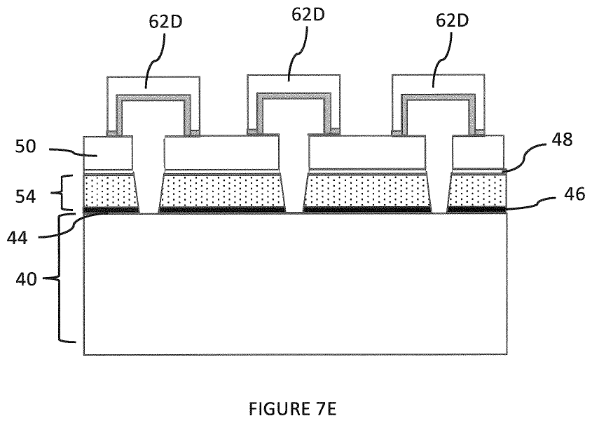

Example 2: Referring to FIGS. 7A-7E, an exemplary fabrication sequence for forming plated connecting metal layers (C-ML) 62P (FIG. 7E) is illustrated. In FIG. 7A, PR50 dry film photoresist is formed over the metal layer openings 52 patterned substantially as shown. In FIG. 7B, second metal layers 76 are formed on the metal layer 50 and on the PR50 photoresist. In FIG. 7C, a 2nd PR50 photoresist is formed on the second metal layers 76 patterned substantially as shown. In FIG. 7D, a C-ML plating 78 is formed on the second metal layers 76. In FIG. 7E, the PR50 photoresist and the 2nd PR50 photoresist are removed leaving the plated connecting metal layers (C-ML) 62P. In this example the C-ML can comprise Cu substantially as previously described.

While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

What is claimed is:

1. A method for fabricating semiconductor devices comprising:
providing an engineered substrate (ES) comprising a core, an engineered layer (ELY) on the core and a lattice matching layer (LML) on the engineered layer (ELY);
providing a plurality of epitaxial (EPI) layers on the lattice matching layer (LML) of the engineered substrate (ES);
forming a plurality of device epitaxial (EPI) structures in the epitaxial (EPI) layers separated by streets;
forming a plurality of connecting metal layers (C-ML) connecting the device epitaxial (EPI) structures; and
removing the core of the engineered substrate (ES) from the device epitaxial (EPI) structures.

2. The method of claim 1 further comprising attaching a temporary substrate to the device epitaxial structures and performing additional fabrication steps.

3. The method of claim 2 wherein the temporary substrate comprises a UV release substrate.

4. The method of claim 1 wherein the forming the device epitaxial (EPI) structures step includes the steps of depositing contact metals on the epitaxial (EPI) layers; forming a metal layer on the contact metals having a plurality of openings in a selected pattern; and using the metal layer to define the device epitaxial (EPI) structures.

5. The method of claim 1 wherein the forming the device epitaxial (EPI) structures step comprises dry etching of the epitaxial (EPI) layers.

6. The method of claim 1 wherein the device epitaxial (EPI) structures comprise semiconductor islands having a polygonal outline.

7. The method of claim 1 wherein the epitaxial (EPI) layers comprise a material selected from the group consisting of Si, C, GaN, AlN, SiC, AlGaN, InGaN, AlCGaN, and AlSiGaN.

8. The method of claim 1 wherein the epitaxial (EPI) layers comprise at least one element selected from the group consisting of Ga, Si, C and In.

9. The method of claim 1 wherein the engineered layer (ELY) comprises at least one element selected from the group consisting of Si, O, N and C.

10. The method of claim 1 wherein the lattice matching layer (LML) comprises at least one element selected from the group consisting of Si, Al, C and N.

11. The method of claim 1 wherein the lattice matching layer (LML) comprises a material selected from the group consisting of Si, C, SiC, GaN, AlN, AlGaN, InGaN, AlCGaN, and AlSiGaN.

12. The method of claim 1 wherein the connecting metal layers (C-ML) comprise a metal selected from the group consisting of Ni, Co, Cu, Ti, Cr, Mo, W, Au, Ag and Pt.

13. The method of claim 1 wherein the forming the plurality of connecting metal layers (C-ML) step comprises photopatterning and electro plating.

14. A method for fabricating semiconductor devices comprising:
providing an engineered substrate (ES) comprising a core, an engineered layer (ELY) on the core and a lattice matching layer (LML) on the engineered layer (ELY);
providing a plurality of epitaxial (EPI) layers on the lattice matching layer;
forming a plurality of epitaxial (EPI) structure islands (EPI-ISL) in the epitaxial (EPI) layers separated by streets by depositing contact metals on the epitaxial (EPI) layers, forming a metal layer on the contact metals having a plurality of openings in a selected pattern, and using the openings in the metal layer to define the epitaxial (EPI) structure islands (EPI-ISL) and to remove the contact metals bounded by the openings;
forming a plurality of connecting metal layers (C-ML) connecting the epitaxial (EPI) structure islands (EPI-ISL); and
removing the core of the engineered substrate (ES) leaving new device structures.

15. The method of claim 14 further comprising attaching a temporary substrate to the epitaxial (EPI) structure islands (EPI-ISL) and performing additional fabrication steps.

16. The method of claim 14 wherein the openings in the metal layer align with the streets.

17. The method of claim 14 wherein the forming the connecting metal layers (C-ML) step comprises forming a first photoresist in the openings, forming a second photoresist on the metal layer having second openings, depositing a metal in the second openings, and removing the first photoresist and the second photoresist.

18. The method of claim 14 wherein the forming the connecting metal layers (C-ML) step comprises forming a first photoresist over the openings, depositing second metals on the metal layer and the first photoresist, forming a second photoresist on the metal layer, plating a C-ML plating on the first photoresist and the second photoresist, and removing the first photoresist and the second photoresist.

19. The method of claim 14 wherein the epitaxial (EPI) layers comprise a material selected from the group consisting of Si, C, GaN, AlN, SiC, AlGaN, InGaN, AlCGaN, and AlSiGaN.

20. The method of claim 14 wherein the metal layer comprises a metal selected from the group consisting of Ni, Co, Cu, Ti, Cr, Mo, W, Au, Ag and Pt.

21. The method of claim 14 wherein the connecting metal layers (C-ML) comprise a metal selected from the group consisting of Ni, Co, Cu, Ti, Cr, Mo, W, Au, Ag and Pt.

22. The method of claim 14 wherein the epitaxial (EPI) layers comprise at least one element selected from the group consisting of Ga, Si, C and In.

23. The method of claim 14 wherein the engineered layer (ELY) comprises at least one element selected from the group consisting of Si, O, N and C.

24. The method of claim 14 wherein the lattice matching layer (LML) comprises at least one element selected from the group consisting of Si, Al, C and N.

25. The method of claim 14 wherein the lattice matching layer (LML) comprises a material selected from the group consisting of Si, C, SiC, GaN, AlN, AlGaN, InGaN, AlCGaN, and AlSiGaN.

26. The method of claim 14 wherein the epitaxial (EPI) structure islands (EPI-ISL) comprise semiconductor islands having a polygonal outline.

27. The method of claim 14 wherein the epitaxial (EPI) structure islands (EPI-ISL) comprise semiconductor islands having four corners and the connecting metal layers (C-ML) comprise polygons or circles on the four corners.

28. The method of claim 14 wherein the epitaxial (EPI) layers comprise layers having a first coefficient of thermal expansion (CTE) and the core of the engineered substate (ES) has a second coefficient of thermal expansion (CTE) closely matched to the first coefficient of thermal expansion (CTE).

29. The method of claim 14 wherein the semiconductor device comprises a device selected from the group consisting of power devices, RF devices, and light emitting diodes (LEDs).
